(19) United States
(12) Patent Application Publication
(10) Pub. No.: US 2022/0206052 A1
(43) Pub. Date: Jun. 30, 2022

(54) FAR-FIELD ANTENNA PATTERN MEASURING SOLUTION & SYSTEM FOR CALIBRATION USING REAL-TIME SYNCHRONIZATION OF HEIGHT INFORMATION

(71) Applicant: VIETTEL GROUP, Ha Noi City (VN)

(72) Inventors: Nhu Thanh Nguyen, Ha Noi City (VN); Ba Duong Vu, Quynh Phu District (VN); Hong Viet Nguyen, Vinh Tuong District (VN); Manh Tuan Nguyen, Ha Noi City (VN)

(73) Assignee: VIETTEL GROUP, Ha Noi City (VN)

(21) Appl. No.: 17/537,498

(22) Filed: Nov. 30, 2021

(30) Foreign Application Priority Data
Dec. 24, 2020 (VN) 1-2020-07503

(51) Int. Cl. G01R 29/10; G01S 13/95

(52) U.S. Cl. CPC G01R 29/10; G01S 13/953

(57) ABSTRACT

Far-field antenna pattern measuring system and solution using real-time synchronization of height information helps better the detecting and tracking quality of the 3D radar, paving the way to determine the pattern's practical shape and the impacts of the ground on it to find the accurate height tracking methods. The proposed system is comprised of 5 steps: step 1: get and save height information; step 2: get and save power information; step 3: plot the obtained pattern shape; step 4: determine the obtained pattern parameters; step 5: save lobes parameters into a table and assess in the association with the simulation results.

### FIELD OF THE INVENTION

The invention relates to the system and solution of far-field antenna pattern measuring using real-time synchronization of height information. In detail, the invention is considered in association to three dimensions (3D) radar systems.

### BACKGROUND OF THE INVENTION

Far-field antenna pattern measuring system and method using real-time synchronization of height information is applied to new generation of 3D radar systems to calculate the practical parameters of radiation pattern (beam width, side lobe level, steering direction).

As for 3D radars designing, since the vertical plane of the pattern has a significant impact on detecting and height measuring ability, it is essential that the influence of practical environment (landscape) on the vertical plane of radar pattern be assessed. This issue has led to the need of researching and proposing the means to measuring and calibrating the far-field radar pattern of 3D radars, leading to the idea of exerting flying drones carrying a transponder combined with radar antenna receiving its signal to plot the pattern's shape. Internationally, there have been methods using flying gadgets to measure radar pattern, in detail, these existing measures use flying device as a receiver of radar signals and use wireless networks to transfer data, which limits the measuring range. Meanwhile, Viettel's proposal uses a drone as a transmitting device, applying LORA (Long range wireless transceiver) to transfer and receive data between ground radar and drone, letting the communicating range be up to 3 km and offering better assessment of antenna's vertical plane. It is also noteworthy that this method helps saving space and weight of the transmitter as well as guarantees the quality of the assessment. This not only helps bettering the detecting and tracking quality of 3D radar systems, but also paves the way to determine the pattern's practical shape and the impacts of the ground on it to find the accurate height tracking methods.

### SUMMARY OF THE INVENTION

Firstly, the most important objective of this invention is to propose the far-field antenna pattern measuring system for 3D radar to calculate antenna parameters. To achieve this, the mentioned system includes a flying device and two main components: the signal transceiver and the ground data receiving component, to be specific:
The aerial device: Flying and carrying
Transceiver: Wave forming in the active beam width of the radar, calculating each point's height, sending height info to the ground via the wireless link. Height of each position is the input of corresponding power measuring process. This component includes: wave-forming circuit (FPGA), height data reading circuit, data transferring circuit.
Ground data-receiving component: receiving height signal through the long range wireless transceiver, this data is then sent to data processor, right after receiving the height value from drone, the processor automatically connects with the spectrum analyzer to get the power info from that position and save it as a file with 2 data fields: height and power, simultaneously displaying pattern shape with plotting points on computer screen. This component includes: long range wireless receiver, data processor, spectrum analyzer.

Secondly, the next objective of the invention is to propose the solution to measure the far-field antenna pattern of the 3D radar system in order to determine pattern's parameters. To achieve this object, the mentioned method requires these following steps:

Step 1: Get and save the height (from ground) data of each point, helping receiving height data of each position.

Step 2: Get and save the power data of each point corresponding to heights received in step 1; the output of this step is the raw power of each position.

Step 3: From height and power data of each position, plot the shape of the pattern; in this step, the plotting lines of height and power is smoothened.

Step 4: Determine the power received by the peak of mainlobe, lobe width, peak power of the sidelobe

Step 5: Compare the results with values obtained with simulation; at this step, antenna pattern quality is considered.

### BRIEF DESCRIPTION OF THE FIGURE

FIG. 1: Diagram of far-field antenna pattern measuring system connection

FIG. 2: Diagram of far-field antenna pattern measuring system elements

FIG. 3: Pratical figure of far-field antenna pattern at the sum channel

FIG. 4: Pratical figure of far-field antenna pattern at the subtract channel

FIG. 5: Pitch minimum error formula

### DETAILED DESCRIPTION OF THE INVENTION

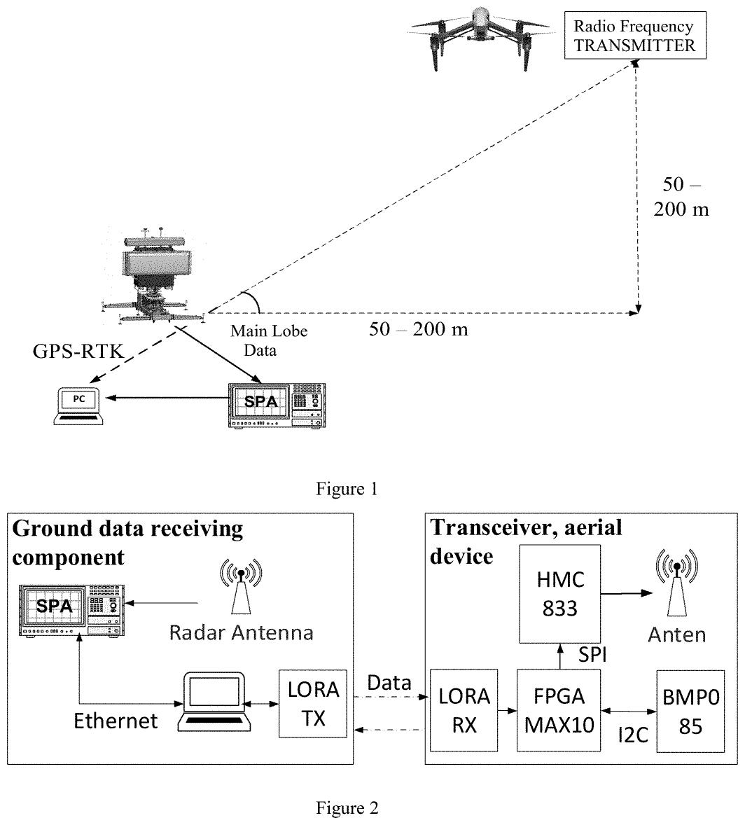

Far-field antenna pattern measurement using real-time synchronization of height information is a subsystem attached to 3D radar systems. According to FIG. 1 and FIG. 2, the system includes:

Aerial device brings the transceiver up from the ground, the highest reachable height of the aerial device is 500 m, so it is vital to calculate the distance on the ground from the aerial device to the center of the radar platform to obtain the pitch error which is suitable to the target. Types of error in the system causing received height info to be inaccurate: error caused by communicating link, error caused by delay time to get data from the spectrum analyzer, error caused by height sensor. Since the height sensor error is the largest among others (1 m), the system error is the height sensor error and hence, the least distance is required to achieve the suitable pitch error is calculated as in FIG. 5.

Where: Suppose h as the current height corresponding to angle α, L is the distance from the center of radar platform to the aerial device on the ground:

$$α = arctan ( \text{h/L} )$$

$$\text{=>} \frac{d α}{dh} = \frac{\frac{1}{L}}{1 + {( \frac{h}{L} )}^{2}} = \frac{L}{{L}^{2} + {h}^{2}} \leq \frac{1}{L}$$

$$\text{=>} σα = \frac{d α}{dh} * σ h \leq \frac{1}{L} * σ h = \frac{1}{L} ( do σ h = 1 m )$$

$$Desired measuring \text{error:} σα \leq {\text{0,3}}^{o} = \frac{\text{0,3} * π}{180}$$

$$\text{=>} L \geq \frac{180}{\text{0,3} * π} \approx \text{191,1} m$$

$$\text{=>} Choose the least measuring \text{distance:} L = 200 m .$$

Transceiver: Generating waveform in the active bandwidth of the radar, calculating each point's height, sending height info to the ground via the wireless link. Height of each position is the input of corresponding power measuring process. This component includes:
Signal generator board: FPGA (Field Programmable Gate Array) controls the phase lock loop (PLL) to generate the signal in the frequency of radar. The signal is the continuous wave. The frequency changing control signal is sent from the ground via the long range wireless transceiver. FPGA controls and monitors the circuit's parameters and guarantees the frequency of signal be equal to frequency of radar. The height information is calculated by FPGA using parameters from pressure sensor circuit; height data is the height from the mean sea level (called “msl” from now on). The height data is sent to the ground via the long range wireless transceiver. The maximum communicating range: 3 km.
Pressure sensor circuit: The height data is obtained by FPGA communicating with a pressure sensor (suitably a BMP085 Barometric Pressure/Temperature/Altitude Sensor), from atmospheric pressure value receiver by FPGA to transferred pressure data corresponding to height. Due to the changing by time in the mean sea level, the process of measuring the antenna pattern must not last so long.
Data transferring circuit: height data and frequency control signal are transferred via the long range wireless transceiver between the ground and the aerial device. Right after obtaining the height data, this data is taken to the long range wireless transceiver to be transferred to the ground.

Ground data-receiving component: receiving height signal through the long range wireless transceiver, this data is then sent to data processor, right after receiving the height value from drone, the processor automatically connect with the spectrum analyzer to get the power info from that position and save it as a file with 2 data fields: height and power, simultaneously display pattern shape with plotting points on computer screen. This component includes:
Long range wireless transceiver (LORA): height data sent from transceiver component to the ground, the wireless transceiver decode the message to get the returned height.
The data processor: collects the decoded height data then gets the corresponding power value in the spectrum analyzer to create a height-power data field. After obtaining the information of height-power, the processor displays the obtained pattern shape and simultaneously saves the data into a file.
Spectrum analyzer: measures power value received from radar antenna, then transfer power data to computer program via the Internet outlet as receiving power data updating signal.

Far-field antenna pattern measuring system and method using real-time synchronization of height information comprise these following step:

Step 1: Get and Save Height Info

With each distinct flying height (aerial device carrying the transceiver takes off from the ground 200 m apart from the radar platform center, as the maximum possible pitch error is 0.3°), FPGA gets the pressure value returned from the pressure sensor circuit BMP085 to calculate the corresponding msl height. The height data is then transferred to the long range wireless transceiver on the ground and saved. At the end of the step, the height value of current position is received before getting power info.

Step 2: Get and Save the Power Value Info

Equivalent to each obtained height, the processor, connecting with spectrum processor via TCP/IP network, gets the power data returned from spectrum analyzer. After being obtained, the power value is matched with height to create a data field. This step is repeated until the last received height value. The output is height-power data.

Step 3: Plot the Received Pattern Shape

After being saved, the height-power data is display as a figure on the screen. This data will be smoothened to form a complete lobes shape. Height data can be gotten until the end of sidelobes are then taken in for analyzation.

Step 4: Determine the Obtained Pattern Parameters

The obtained pattern parameters are: power of the mainlobe, mainlobe width, mainlobe and sidelobe peak power difference. Peak power of the mainlobe should approximately equal to that of theoretical calculation at the same distance. If the difference is too significant, some of the system parameters are functioning wrong.

The directional angle of the mainlobe is computed as follow:

ω=A tan(x/d);

As: d is the distance from radar platform center to the flying position, co is the obtained directional angle position.

Mainlobe width is computed as the width between two P3 dB points on the two sides of the lobe (3 dB Compression Point or P3 dB is the power level at which signal decreases by 3 dB from its ideal). Name the heights corresponding to mainlobe position P3 dB_1 (on the left side of the lobe) and P3 dB_2 (on the right side of the lobe) as x₁, x₂, respectively. The mainlobe width is calculated as follow:

Φ=|A tan(x₁/d)−A tan(x₂/d)|;

As: Φ is the obtained lobe width, d is the distance from radar platform center to the flying position.

The power difference between mainlobe and sidelobe peak is calculated by subtracting mainlobe peak power to sidelobe peak power.

Step 5: Save Lobes Parameters into a Table and Compare in the Association with the Simulation Results.

The obtained value of power of the mainlobe, mainlobe width, mainlobe and sidelobe peak power difference are compared with the simulation values, then the 3D radar pattern quality can be assessed.

### Efficiency of Invention

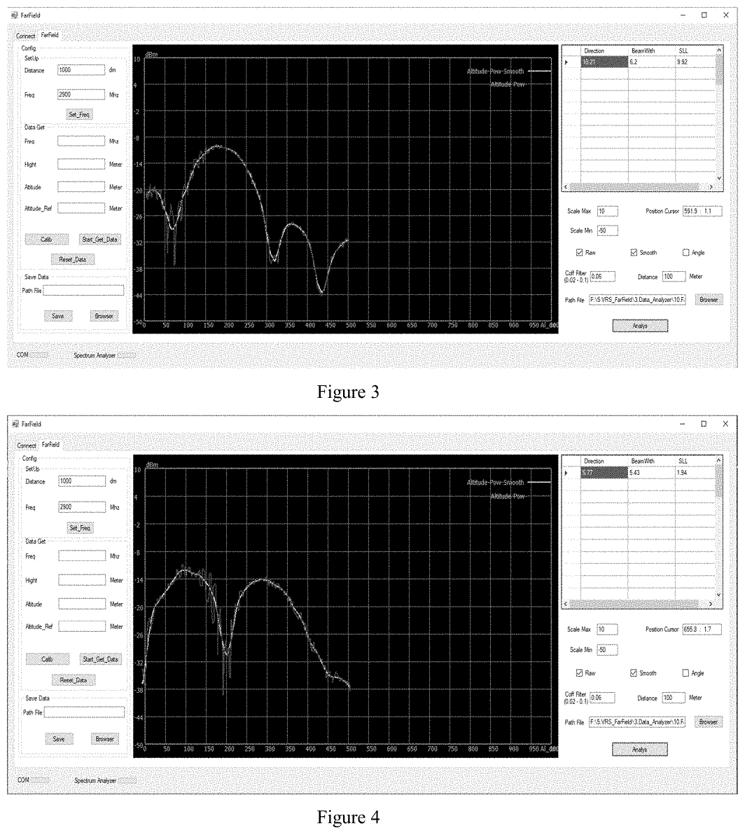

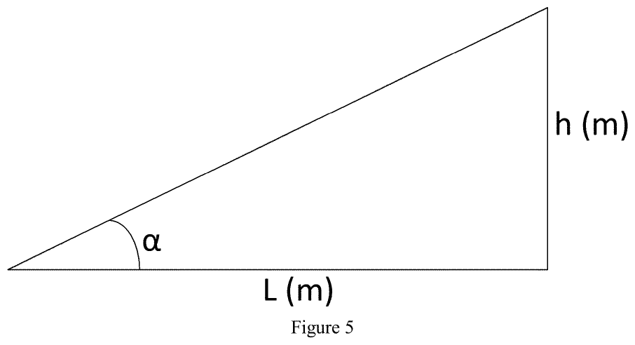

Practical results with 3D radars has showed that this new measuring solution is able to output the radar pattern parameters and can assess the pattern quality of the 3D radar system (FIG. 3 and FIG. 4). Received results after a number of measurements:

| | | | Sum Channel | | | Diff Channel |
|---|---|---|---|---|---|---|
| | | Theoretical | Measured | | | Measured |
| Order | | Pitch | Pitch | Beam Width | Sidelobe | Pitch |
| ID | Date | [°] | [°] | [°] | [dB] | [°] |
| 1 | Sep. 13, 2019 | 21.8879 | 22.49 | 6.43 | 8.5 | |
| 2 | Sep. 13, 2019 | 21.8879 | 22.64 | 6.37 | 8.84 | |
| 3 | Sep. 16, 2019 | 21.8879 | 20.91 | 6.76 | 11.27 | 21.7 |
| 4 | Sep. 17, 2019 | 9.9944 | 9.9926 | 5.4 | 9.6 | 10.87 |

As can be seen from the received results, the solution to measure the vertical plane of the far-field pattern offers the error under 10% in comparison to the theoretical pitch. Thus, this method is applicable to calculating the practical vertical plane parameters of the 3D radar system.

While a preferred embodiment of the present invention has been shown and described, it will be apparent to those skilled in the art that many changes and modifications may be made without departing from the invention in its broader aspects. The appended claims are therefore intended to cover all such changes and modifications as fall within the true spirit and scope of the invention.

1. Far-field antenna pattern measuring system using real-time synchronization of height information, including:
An aerial device that brings a transceiver up from the ground, the highest reachable height of the aerial device is 500 m, to calculate the distance on the ground from the aerial device to the center of radar platform to obtain a pitch error which is suitable to a target, Types of error in the system causing received height info to be inaccurate are: error caused by communicating link, error caused by delay time to get data from the spectrum analyzer, error caused by height sensor, wherein since height sensor error is the largest among others (1 m), the pitch system error is chosen as the height sensor error, Suppose h as a current height corresponding to angle α, L is the distance from the center of radar platform to the aerial device when on the ground, we have:
$$α = arctan ( \text{h/L} )$$
$$\text{=>} \frac{d α}{dh} = \frac{\frac{1}{L}}{1 + {( \frac{h}{L} )}^{2}} = \frac{L}{{L}^{2} + {h}^{2}} \leq \frac{1}{L}$$
$$\text{=>} σα = \frac{d α}{dh} * σ h \leq \frac{1}{L} * σ h = \frac{1}{L} ( do σ h = 1 m )$$
$$Desired measuring \text{error:} σα \leq {\text{0,3}}^{o} = \frac{\text{0,3} * π}{180}$$
$$\text{=>} L \geq \frac{180}{\text{0,3} * π} \approx \text{191,1} m$$
$$\text{=>} Choose the least measuring \text{distance:} L = 200 m ;$$
a transceiver: Generating waveform in an active radar bandwidth, calculating each point's height, sending height info to the ground via a wireless link, wherein height of each position is an input of corresponding power measuring process, wherein this component includes:
Signal generator board: a FPGA (Field Programmable Gate Array) controls a phase lock loop (PLL) to generate a signal in the frequency of radar, wherein the signal is a continuous wave, a frequency changing control signal is sent from the ground via a long range wireless transceiver, the FPGA controls and monitors parameters and guarantees the frequency of signal be within frequency of radar, the height information is calculated by the FPGA using parameters from a pressure sensor circuit; height data is the height from msl (mean sea level), wherein the height data is sent to the ground via the long range wireless transceiver, wherein the maximum communicating range: 3 km;
The pressure sensor circuit comprising: the height data is obtained by the FPGA communicating with pressure sensor BMP085, from atmospheric pressure value receiver by FPGA to transferred pressure data corresponding to height, due to changing by time in the reference pressure, the process of measuring the antenna pattern must not so long;
a data transferring circuit: height data and frequency control signal are transferred via the long range wireless transceiver between the ground and the aerial device, right after obtaining the height data, this data is taken to the long range wireless transceiver to be transferred to the ground;
a ground data receiving component: receiving height signal through the long range wireless transceiver, this data is then sent to a data processor, right after receiving the height value from drone, the processor automatically connects with a spectrum analyzer to get power information from that position and save it as a file with 2 data fields: height and power, simultaneously display pattern shape with plotting points on a computer screen, wherein this component includes:
a long range wireless transceiver (LORA): height data sent from transceiver component to the ground, the wireless transceiver decodes the message to get the returned height,
a data processor: collects the decoded height data then gets the corresponding power value in the spectrum analyzer to create a height-power data field. After obtaining the information of height-power, the processor displays the obtained pattern shape and simultaneously saves the data into a file,
a spectrum analyzer: measures power value received from radar antenna, then transfer power data to computer program via the LAN port as receiving power data updating signal.

2. Far-field antenna pattern measuring system and method using real-time synchronization of height information comprises the following step:
Step 1: Get and save height info,
with each distinct flying height (an aerial device carrying the transceiver takes off from the ground 200 m apart from a radar platform center, as the maximum possible pitch error is 0.3°), a FPGA gets the pressure value returned from a pressure sensor circuit BMP085 to calculate a corresponding msl height, the height data is then transferred to a long range wireless transceiver on the ground and saved, at the end of the step, the height value of current position is received before getting power information;
Step 2: Get and save the power value info,
Equivalent to each obtained height, the processor, connecting with a spectrum processor via a TCP/IP network, gets the power data returned from the spectrum analyzer, after being obtained, the power value is matched with height to create a data field, this step is repeated until a last received height value, the output is height-power data;
Step 3: Plot the received pattern shape,
After being saved, the height-power data is display as a figure on a screen. This data will be smoothened to form a complete lobes shape. Height data can be gotten until the end of sidelobes are then taken in for analysis;
Step 4: Determine the obtained pattern parameters,
The obtained pattern parameters are: power of the mainlobe, mainlobe width, mainlobe and sidelobe peak power difference, peak power of the mainlobe should approximately equal to that of theoretical calculation at the same distance, if the difference is too significant, some of the system parameters are functioning wrong;
The directional angle of the mainlobe is computed as follow:
ω═A tan(x/d);
As: d is the distance from radar platform center to a flying position, co is the obtained directional angle position,
Mainlobe width is computed as a width between two P3 dB points on the two sides of the lobe, name the heights corresponding to mainlobe position P3 dB_1 (on the left of the peak) and P3 dB_2 (on the right of the peak) as x₁, x₂, respectively, the mainlobe width is calculated as follow:
Φ=|A tan(x₁/d)−A tan(x₂/d)|;
As: Φ is the obtained lobe width, d is the distance from radar platform center to the flying position,
The power difference between mainlobe and sidelobe peak is calculated by subtracting mainlobe peak power to sidelobe peak power in decibel;
Step 5: Save lobes parameters into a table and compare to simulation results,
The obtained value of power of the mainlobe, mainlobe width, mainlobe and sidelobe peak power difference are compared to the simulation values, then the 3D radar pattern quality can be assessed.
